(19) United States
(12) Patent Application Publication
(10) Pub. No.: US 2022/0122978 A1
(43) Pub. Date: Apr. 21, 2022

(54) MEMORY AND ITS MANUFACTURING METHOD

(71) Applicant: CHANGXIN MEMORY TECHNOLOGIES, INC., Hefei City (CN)

(72) Inventors: Xing JIN, Hefei City (CN); Ming Cheng, Hefei City (CN); Ran Li, Hefei City (CN)

(21) Appl. No.: 17/480,379

(22) Filed: Sep. 21, 2021

Related U.S. Application Data
(63) Continuation of application No. PCT/CN2021/103801, filed on Jun. 30, 2021.

(30) Foreign Application Priority Data
Oct. 15, 2020 (CN) 202011103503.3

(51) Int. Cl. H01L 27/108

(52) U.S. Cl. CPC H01L 27/10805; H01L 27/10888; H01L 27/1085

(57) ABSTRACT

A memory and its manufacturing method are disclosed herein. The memory includes a substrate, active region in the substrate, and bitline structures on the substrate, the active region extending in a first direction; and capacitor contact windows, the capacitor contact window being located between adjacent ones of the bitline structures, at least one center line of a bottom surface of the capacitor contact window extending in a second direction, an angle between the second direction and the first direction being less than or equal to 45 degrees. The present disclosure is beneficial to improving the signal transmission performance of the memory.

### CROSS-REFERENCE TO RELATED APPLICATIONS

This application is a continuation application of International Patent Application No. PCT/CN2021/103801, filed on Jun. 30, 2021, which claims priority to Chinese Patent Application No. 202011103503.3, filed on Oct. 15, 2020. International Patent Application No. PCT/CN2021/103801 and Chinese Patent Application No. 202011103503.3 are hereby incorporated by reference into the present disclosure in their entireties.

### TECHNICAL FIELD

Embodiments of the present disclosure relate to the field of semiconductors, and in particular to a memory and its manufacturing method.

### BACKGROUND

As a feature size of semiconductor integrated circuit devices continues to shrink, a size change in a certain element will have a greater impact on the overall performance of a semiconductor structure, such as the size change in a bitline structure.

Specifically, increasing the feature size of the bitline structure will decrease the space of a capacitor contact hole and reduce the cross-sectional area of a capacitor contact window. A smaller cross-sectional area of the capacitor contact window will easily cause poor contact, which will result in a failure of a storage capacitor; reducing the feature size of the bitline structure will easily cause the bitline structure to collapse due to an excessively large aspect ratio.

How to optimize the performance of a semiconductor structure without changing the feature size of specific components is the focus of current research.

### SUMMARY

Various embodiments of the present disclosure provide a memory and its manufacturing method, which are beneficial to improving the signal transmission performance of the memory.

An embodiment of the present disclosure provides a memory, including: a substrate, active region in the substrate, and bitline structures on the substrate, the active region extending in a first direction; and capacitor contact windows, the capacitor contact window being located between adjacent ones of the bitline structures, at least one center line of a bottom surface of the capacitor contact window extending in a second direction, an angle between the second direction and the first direction being less than or equal to 45 degrees.

Correspondingly, an embodiment of the present disclosure further provides a manufacturing method of a memory, including: providing a substrate, active region in the substrate, and bitline structures on the substrate, the active region extending along a first direction; forming a sacrificial layer filled between adjacent ones of the bitline structures, and forming a mask layer covering a top surface of the sacrificial layer, the mask layer being configured to form an isolation layer; and forming the isolation layer and capacitor contact windows between adjacent ones of the isolation layers, at least one center line of a bottom surface of the capacitor contact window extending in a second direction, an angle between the second direction and the first direction being less than or equal to 45 degrees.

The technical solution according to the embodiments of the present disclosure has the following advantages.

In the above technical solution, by controlling the angle between an extension direction of at least one center line of the bottom surface of the capacitor contact window and an extension direction of the active region to be less than or equal to a predetermined value, misalignment between the capacitor contact window and the active region is reduced; in this case, when the bottom surfaces of the capacitor contact windows are the same in area, an contact area between the bottom surface of the capacitor contact window and the active region is relatively large, thus ensuring a good signal transmission performance of the capacitor contact window.

### BRIEF DESCRIPTION OF DRAWINGS

One or more embodiments are illustrated by way of example, and not by limitation, in the figures of the accompanying drawings, wherein elements having the same reference numeral designations represent like elements throughout. The drawings are not to scale, unless otherwise disclosed.

FIGS. 1 to 23 are schematic structural diagrams corresponding to various steps in a manufacturing method of a memory according to an embodiment of the present disclosure.

### DESCRIPTION OF EMBODIMENTS

In order to make the objectives, technical solutions, and advantages of the embodiments of the present disclosure more clear, various embodiments of the present disclosures will be detailed below in combination with the accompanying drawings. However, a person of ordinary skill in the art can understand that in each embodiment of the present disclosure, many technical details are provided for readers to better understand the present disclosure. However, even if these technical details are not provided and based on variations and modifications of the following embodiments, the technical solutions sought for protection in the present disclosure can also be implemented.

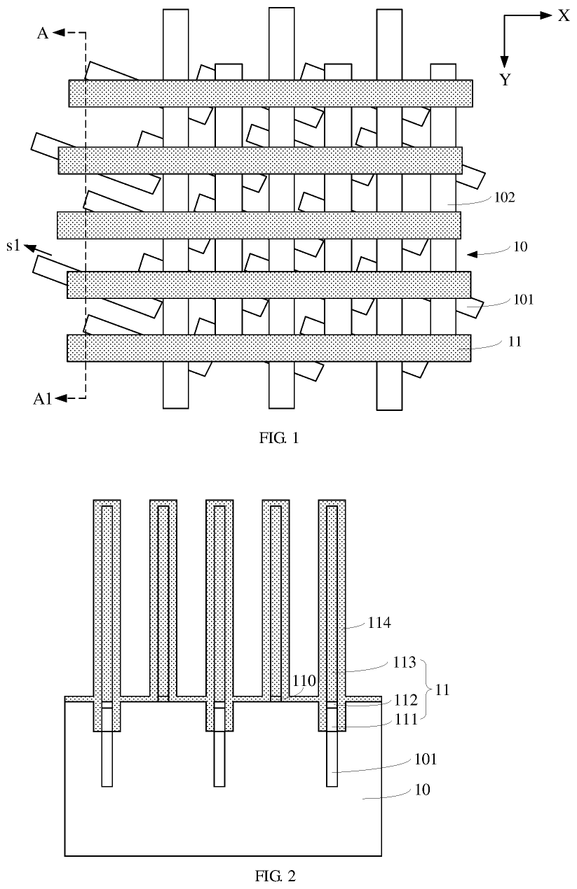

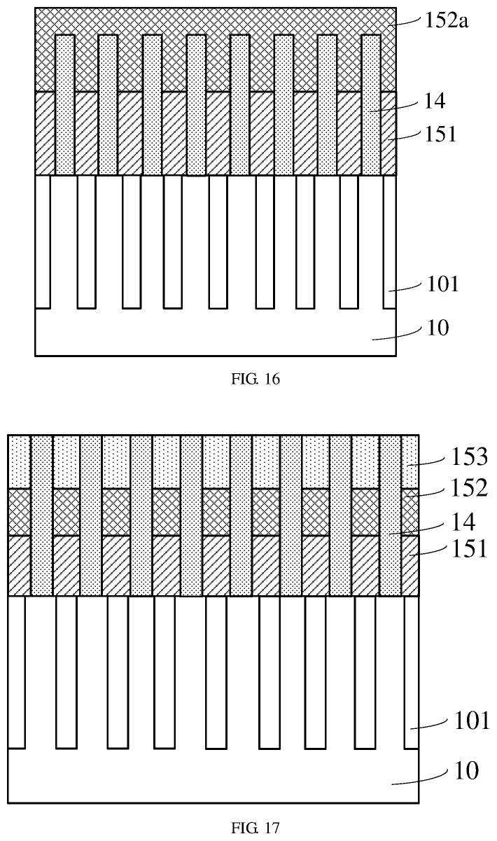

FIGS. 1 to 23 are schematic structural diagrams corresponding to various steps in a manufacturing method of a memory according to embodiments of the present disclosure.

FIG. 1 is top view corresponding to various steps in a first manufacturing method of a memory according to an embodiment of the present disclosure. FIG. 2 is a schematic cross-sectional structural diagram of the structure shown in FIG. 1 along a first cross-sectional direction AA1.

Referring to FIGS. 1 and 2, a substrate 10, active region 101 in the substrate 10, bitline structures 11 on the substrate 10, and isolation films 114 are provided.

The active region 101 extends along a first direction s1.

The bitline structure 11 includes a first conductive layer 111, a second conductive layer 112, and a top medium layer 113 which are stacked in sequence. The first conductive layer 111 and the second conductive layer 112 are located in the substrate 10, and the first conductive layer 111 is in contact with the active region 101. The bitline structure 11 further includes a bottom medium layer 110, and the bottom medium layer 110 is configured to define a position of the first conductive layer 111 and a position of the second conductive layer 112.

The isolation film 114 covers a top surface of the bitline structure 11 and sidewalls of the bitline structure 11, and specifically covers a top surface of the top medium layer 113, sidewalls of the top medium layer 113, and sidewalls of the bottom medium layer 110, as well as a surface of the substrate 10.

In some embodiments, the substrate 10 is further provided with buried wordlines 102 therein. The bitline structure 11 extends along a first coordinate direction X, the buried wordline 102 extends along a second coordinate direction Y, and the first coordinate direction X is perpendicular to the second coordinate direction Y. In other embodiments, in a same plane, an angle between the first coordinate direction and the second coordinate direction is less than 90 degrees.

Referring to FIG. 3, a sacrificial layer 12 filled between adjacent ones of the bitline structures 11 is formed, and a bonding layer 131 covering a top surface of the sacrificial layer 12 is formed.

For a same etching process, there is a larger etch selectivity ratio between a material of the sacrificial layer 12 and a material of the isolation film 114. In this way, an etching agent for removing the sacrificial layer 12 can be prevented from etching the material of the isolation film 114, thus ensuring that the bitline structure 11 has a good signal transmission performance. Specifically, the material of the sacrificial layer 12 may be Spin-on Dielectrics (SOD), such as silicon dioxide, and the material of the isolation film 114 may be silicon nitride.

The bonding layer 131 is configured to fix the sacrificial layer 12 and a mask layer to be formed subsequently, so as to prevent the mask layer from shifting during the process, thereby improving a masking accuracy of the mask layer, improving a position accuracy of the capacitor contact window formed by using the mask layer, ensuring a relatively good electrical conductivity between the capacitor contact window and the active region 101, and further enabling the memory to have a good signal transmission performance.

The bonding layer 131 may be made of tetraethyl orthosilicate (TEOS).

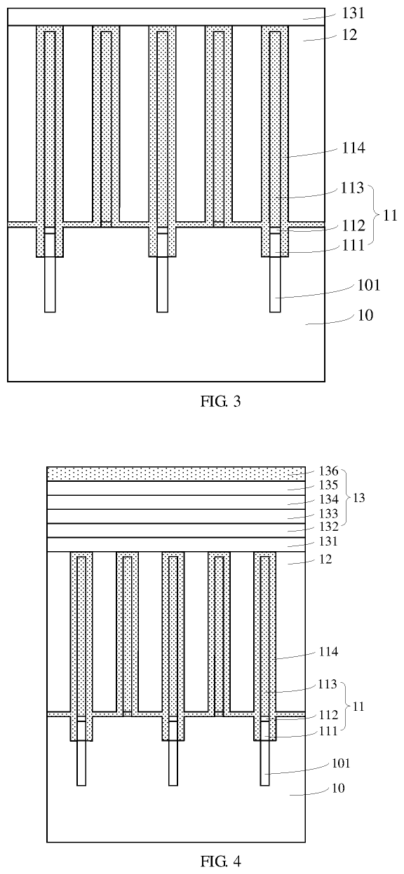

Referring to FIG. 4, a mask layer 13 covering a top surface of the bonding layer 131 is formed.

The mask layer 13 may be of a single-layer structure or of a structure with multiple layers stacked in sequence.

In some embodiments, the mask layer 13 includes a first sub-mask layer 132, a second sub-mask layer 133, a third sub-mask layer 134, a fourth sub-mask layer 135, and a fifth sub-mask layer 136 which are stacked in sequence. A material of the first sub-mask layer 132 may include a carbon-containing compound, a material of the second sub-mask layer 133 may include silicon oxynitride, the third sub-mask layer 134 may be configured as an SOC (Spin-on Carbon) layer, the fourth sub-mask layer 135 may be of an SHB (Si—O-based Hard Mask) intermediate layer structure, and the fifth sub-mask layer 136 is configured as a photoresist layer.

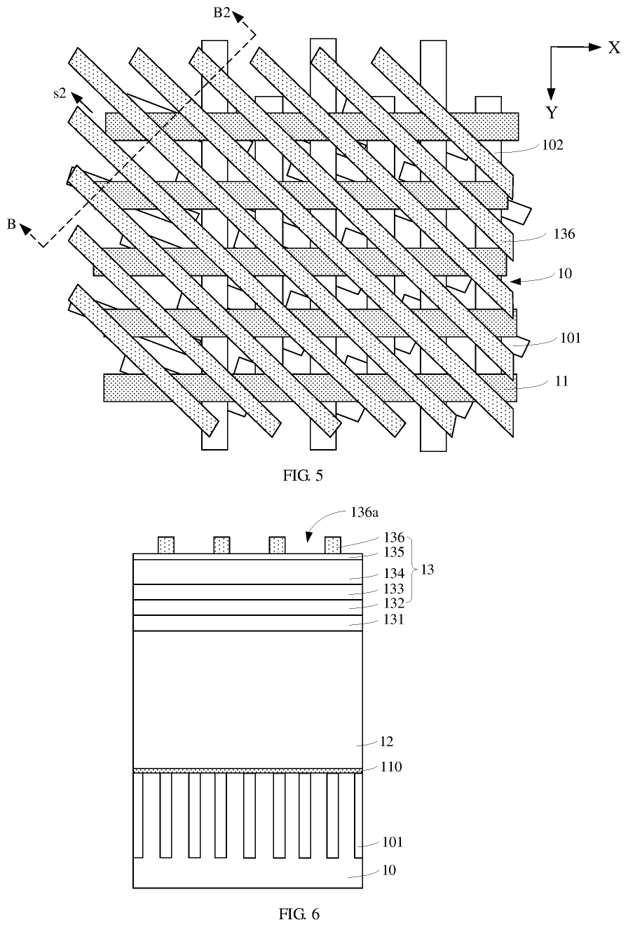

Referring to FIGS. 5 and 6, the fifth sub-mask layer 136 is exposed to form patterned openings 136a.

FIG. 5 is a top view of the structure shown in FIG. 4 after the exposure process; and FIG. 6 is a schematic cross-sectional structural diagram of the structure shown in FIG. 5 along a second cross-sectional direction BB2.

The exposed fifth sub-mask layer 136 is composed of a plurality of parallel and discrete mask strips, and extension directions of the different mask strips are the same; the exposed fifth sub-mask layer 136 is used to define position of the capacitor contact window to be subsequently formed, and specifically to define the extension direction of at least one center line of a bottom surface of the capacitor contact window, so that the extension direction of the at least one center line of the bottom surface of the capacitor contact window is the same as the extension direction of the mask strip. In some embodiments, the mask strip extends along a second direction s2, and an angle between the second direction s2 and the first direction s1 is less than or equal to 45 degrees, such as 30 degrees, 20 degrees, or 10 degrees. In this way, by controlling the angle between an extension direction of at least one center line of the bottom surface of the capacitor contact window and an extension direction of the active region to be less than or equal to a predetermined value, misalignment between the bottom surface of the capacitor contact window and the active region is reduced; in this case, when the bottom surfaces of the capacitor contact windows are the same in area, an contact area between the bottom surface of the capacitor contact window and the active region is relatively large, thus ensuring a good signal transmission performance of the capacitor contact window.

In some embodiments, after the fifth sub-mask layer 136 is formed, the sacrificial layer 12 is etched by an SADP (Self-aligned Double Patterning) process to form an isolation trench to be filled with a first isolation layer. The specific process steps of the SADP process are as follows.

Referring to FIG. 7, the third sub-mask layer 134 and the fourth sub-mask layer 135 are etched, and a sixth sub-mask layer 137 is formed.

Specifically, the third sub-mask layer 134 and the fourth sub-mask layer 135 are etched through the patterned opening 136a (see FIG. 6), and after the third sub-mask layer 134 is etched through to expose the second sub-mask layer 133, the remaining fifth sub-mask layer 136 (see FIG. 6) is removed; a deposition process is carried out to form the sixth sub-mask layer 137, and the sixth sub-mask layer 137 covers a top surface of the fourth sub-mask layer 135, sidewalls of the fourth sub-mask layer 135, sidewalls of the third sub-mask layer 134, and a top surface of the second sub-mask layer 133.

In some embodiments, the sixth sub-mask layer 137 has reserved grooves 137a therein.

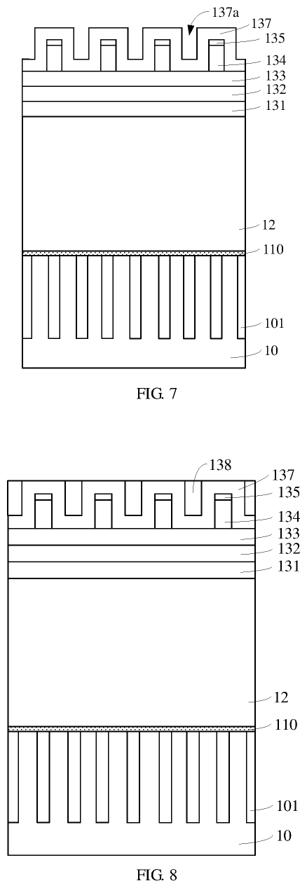

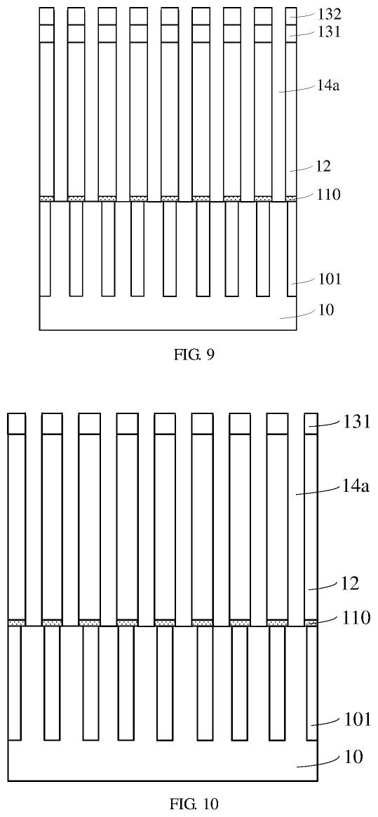

Referring to FIGS. 8 and 9, a seventh sub-mask layer 138 and an isolation trench 14a are formed, and the isolation trench 14a is configured to be filled with the first isolation layer.

In some embodiments, the seventh sub-mask layer 138, the third sub-mask layer 134, and the fourth sub-mask layer 135 are configured to sequentially etch the sixth sub-mask layer 137, the second sub-mask layer 133, the first sub-mask layer 132, the bonding layer 131, the sacrificial layer 12, and the bottom medium layer 110 to form the isolation trench 14a exposing the surface of the substrate 10; after the isolation trench 14a is formed, a first planarization process can be carried out to remove the second sub-mask layer 133, the third sub-mask layer 134, the fourth sub-mask layer 135, the sixth sub-mask layer 137, and the seventh sub-mask layer 138, thereby improving the manufacturing efficiency of the memory.

In other embodiments, the bottom medium layer may not be etched, that is, the isolation trench exposes the surface of the bottom medium layer, and the part of the bottom medium layer exposed by the isolation trench functions as a part of the isolation layer to be formed subsequently, which is beneficial to reducing the process steps and shortening the process cycle.

Since the first sub-mask layer 132 is fixed to the sacrificial layer 12 through the bonding layer 131, the fixing strength is relatively high. If the first sub-mask layer 132 is removed directly by a planarization process, the sacrificial layer 12 indirectly connected to the first sub-mask layer 132 may collapse due to lack of support, or the sacrificial layer 12 may have internal defects.

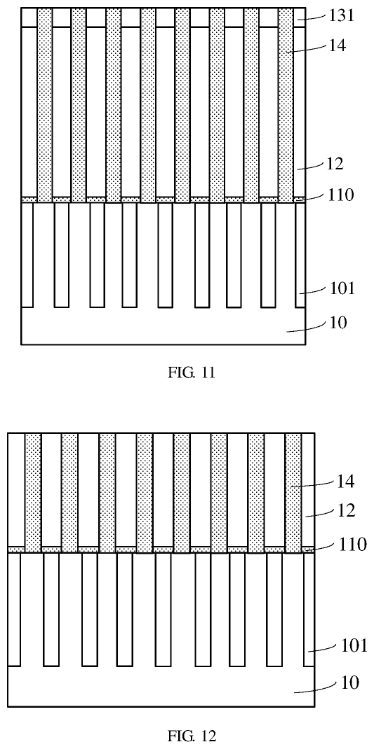

Referring to FIGS. 10 and 11, the first sub-mask layer 132 is removed and the isolation trench 14a is filled to form the first isolation layer 14.

In some embodiments, after the planarization process, the first sub-mask layer 132 is removed by an etching process to prevent the removal of the first mask layer 132 from damaging the intermediate structure or causing process defects, thus ensuring a high yield of the final memory.

Referring to FIG. 12, a second planarization process is carried out to reduce a height of the first isolation layer 14.

In some embodiments, the height of the capacitor contact window to be formed subsequently can be limited by reducing the height of the first isolation layer 14, thereby avoiding structural defects such as collapse and fracture of the first isolation layer 14 and the capacitor contact window due to an excessive aspect ratio, and ensuring that the final memory has good structural stability.

In some embodiments, the bonding layer 131 is removed while reducing the height of the first isolation layer 14.

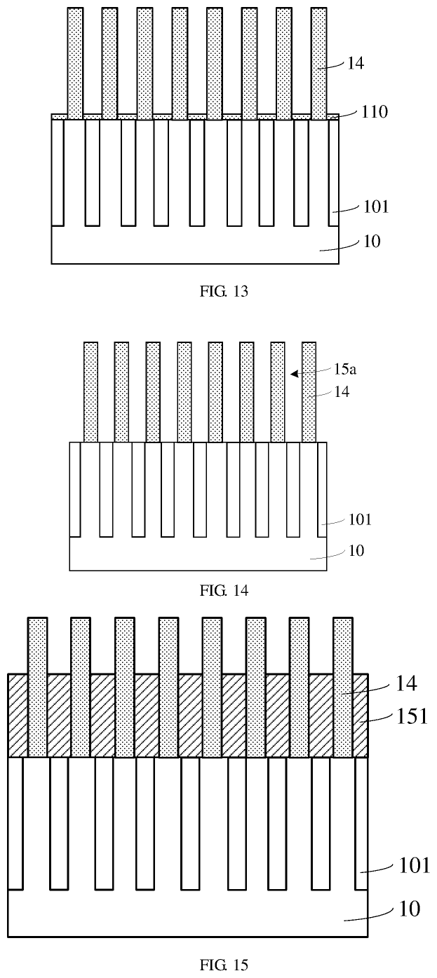

Referring to FIGS. 13 and 14, the remaining sacrificial layer 12 (see FIG. 12) and the part of the bottom medium layer 110 exposed by the first isolation layer 14 are removed to form a capacitor contact hole 15a exposing at least a part of the surface of the active region 101.

In some embodiments, a wet etching process may be carried out to remove the remaining sacrificial layer 12 located between adjacent first isolation layers 14, and a maskless dry etching process may be carried out to remove the part of the bottom medium layer 110 exposed by the first isolation layer 14.

It should be noted that during the process of etching the bottom medium layer 110 using the maskless dry etching process, the first isolation layer 14 will also be etched, that is, the height of the first isolation layer 14 will be further reduced. Therefore, to reach the requirement that the finally formed capacitor contact hole 15a has a predetermined depth, the first isolation layer 14 with a height greater than the predetermined depth needs to be reserved in the second planarization process, and a difference between the actual reserved height and the predetermined depth is equal to a thickness of the bottom medium layer 110 in a direction perpendicular to the substrate 10.

Referring to FIGS. 15 to 17, a conductive film and a shielding layer 153 are formed in the capacitor contact hole 15a (see FIG. 14), and the shielding layer 153 is located on the conductive film.

In some embodiments, the conductive film includes a first conductive film 151 and a second conductive film 152, the first conductive film 151 is in contact with the active region 101, and the second conductive film 152 is located on the first conductive film 151. Both the first conductive film 151 and the second conductive film 152 can be formed by first filling the capacitor contact hole 15a and then performing a dry etching process.

For example, after the first conductive film 151 is formed, a deposition process can be carried out to form a second initial conductive film 152a filling up the capacitor contact hole 14a, a dry etching process can be carried out to etch and remove part of the second initial conductive film 152a, and the remaining second initial conductive film 152a functions as the second conductive film 152.

In some embodiments, by controlling materials of the first conductive film 151 and the second conductive film 152, a contact resistance between the active region 101 and the capacitor contact window composed of the first conductive film 151 and the second conductive film 152 can be reduced so that the final memory has a good signal transmission performance.

Specifically, the active region 101 may be made of monocrystalline silicon, the first conductive film 151 may be made of polysilicon, and the second conductive film 152 may be made of tungsten.

In some embodiments, due to the limitation of the mask stripe, at least one center line of a bottom surface of the first conductive film 151 extends along the second direction. Specifically, in an exemplary embodiment, the bottom surface of the first conductive film 151 is parallelogram-shaped, and short sides of the parallelogram are close to the bitline structure; due to the limitation of the mask strip, long sides of the parallelogram extend along the second direction s2, that is, the center line parallel to the long side extends in the second direction. In other embodiments, the bottom surface of the first conductive film is parallelogram-shaped, and long sides of the parallelogram are close to the bitline structure; due to the limitation of the mask strip, the center line parallel to short sides extends in the second direction.

In some embodiments, for the same etching process, an etch selectivity ratio of a material of the shielding layer 153 to a material of the first isolation layer 14 is greater than 50. In this way, during the process of etching the first isolation layer 14 by the wet etching process, an etching agent can smoothen sidewalls of the shielding layer 153 without causing over-etching, thus ensuring that the smoothened shielding layer 153 has a precise masking effect.

It should be noted that “smoothen” usually can achieve two levels: first, “preliminarily smoothen”, that is, a right angle is ground into a rounded corner; second, “deeply smoothen”, that is, a straight transition is further ground into an arc transition. Specifically, preliminarily smoothening a rhombus can refer to that four rectilinear angles of the rhombus into rounded corners, and the rounded corners are still connected and transitioned by straight lines; deeply smoothening a rhombus can refer to grinding a rhombus into an ellipse. “Smoothen” in the embodiments of the present disclosure refers to “deeply smoothen”.

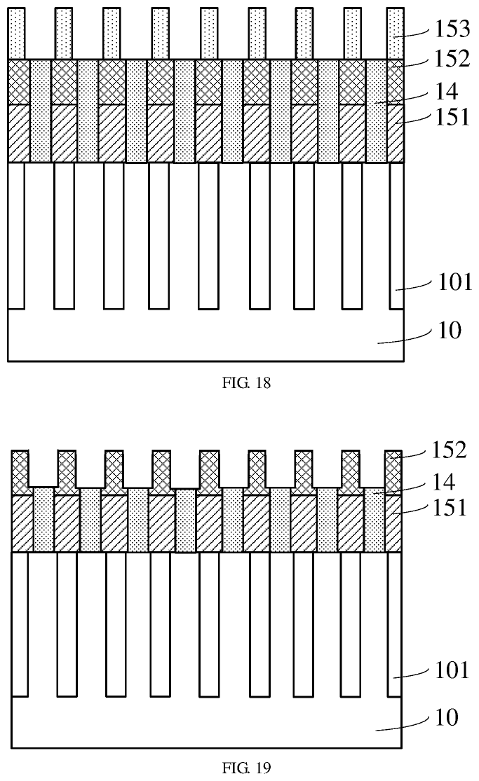

Referring to FIG. 18, a wet etching process is carried out to remove part of the first isolation layer 14 to smoothen the sidewalls of the shielding layer 153.

In some embodiments, the shielding layer 153 includes a plurality of discrete shielding grids, the shielding grids are located in the capacitor contact holes, and smoothening the sidewalls of the shielding layer 153 actually refers to smoothening the sidewalls of each of the shielding grids.

In some embodiments, the shielding grid is parallelogram-shaped before smoothening, and long sides of the parallelogram extend in the second direction s2; after smoothening, the shielding grid becomes an ellipse, and a major axis of the ellipse extends in the second direction s2.

In other embodiments, each of the shielding grids is parallelogram-shaped before smoothening, and short sides of the parallelogram extends in the second direction; after smoothening, the shielding grid becomes an ellipse, and a major axis of the ellipse extends in the second direction s2.

Referring to FIG. 19, at least part of the conductive film is etched by using the smoothened shielding layer 153 (see FIG. 18) as a mask, and the remaining conductive film functions as the capacitor contact window.

In some embodiments, some thickness of the second conductive film 152 and some thickness of the first isolation layer 14 are etched by using the smoothened shielding layer 153 as a mask, a top surface of the etched first isolation layer 14 is higher than that of the first conductive film 151, and a top surface of the etched second conductive film 152 is the same as a top surface of the shielding grid; after the second conductive film 152 is etched, the shielding layer 153 is removed.

In other embodiments, the second conductive film is etched by using the smoothened shielding layer as a mask, and a bottom surface of the etched second conductive film is the same as the top surface of the shielding grid; or, the second conductive film and some thickness of the first conductive film are etched by using the smoothened shielding layer as a mask, the bottom surface of the etched second conductive film is the same as the top surface of the shielding grid, and the top surface of the etched first conductive film is the same as the top surface of the shielding grid; or, the second conductive film and the first conductive film are etched by using the smoothened shielding layer as a mask, and the bottom surface of the etched first conductive film is the same as the top surface of the shielding grid.

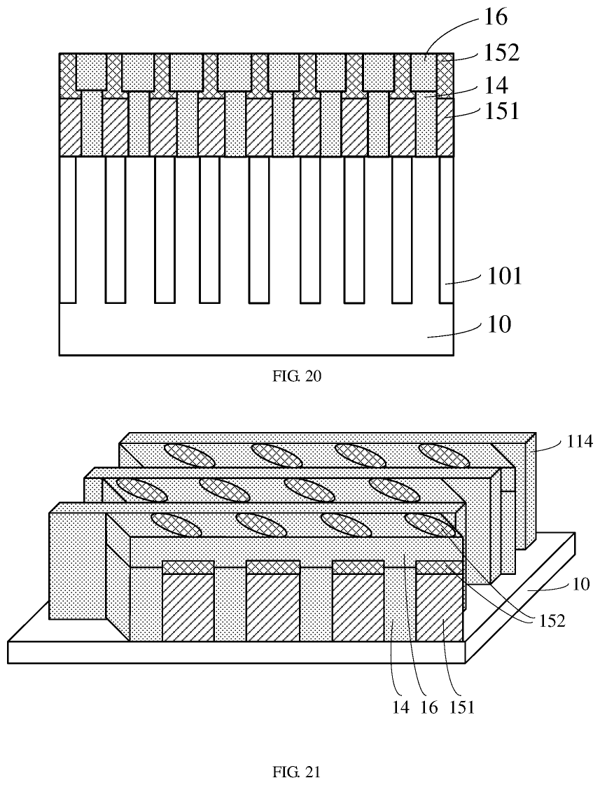

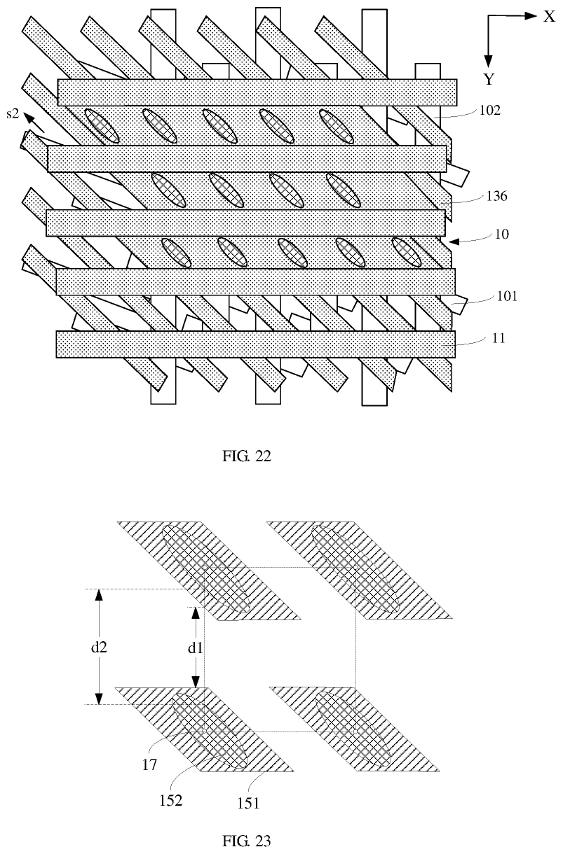

FIG. 21 is a schematic three-dimensional structural diagram of the structure shown in FIG. 20, and FIG. 22 is a top view of the structure shown in FIG. 20. Referring to FIGS. 20 to 22, a second isolation layer 16 is formed.

In some embodiments, after the first isolation layer 14 is etched, the second isolation layer 16 filled between adjacent conductive films is formed. A top surface of the second isolation layer 16 is flush with a top surface of the capacitor contact window. The second isolation layer 16 and the first isolation layer 14 constitute an isolation layer.

A position of the second isolation layer 16 is related to an etched region of the previous etching process, and the second isolation layer 16 fills up grooves etched by the previous etching process.

In some embodiments, referring to FIG. 23, the first conductive film 151 and the second conductive film 152 are distributed in a quadrangular shape. In the direction perpendicular to the surface of the substrate, a central axis of the first conductive film 151 and a central axis of the second conductive film 152 are coincided.

In some embodiments, the central axis of the first conductive film 151 has an orthographic projection point 17 in the direction perpendicular to the surface of the substrate. In a connection direction of adjacent orthographic projection points 17, a first distance d1 between the adjacent first conductive films 151 is less than a second distance d2 between adjacent second conductive films 152, that is, parasitic capacitance between the adjacent second conductive films 152 is less than parasitic capacitance between adjacent first conductive films 151. In other words, smoothening the conductive film is beneficial to reducing the parasitic capacitance between adjacent capacitor contact windows and improving the signal transmission performance of the capacitor contact window.

In some embodiments, only some thickness of the conductive film is further etched to ensure a relatively large contact area between the bottom surface of the conductive film and the active region, thereby achieving a good signal transmission performance between the conductive film and the active region. In other embodiments, the conductive film is etched through so that a pattern on the bottom surface of the conductive film is the same as a pattern on the top surface of the conductive film. In an exemplary embodiment, the pattern on the bottom surface of the conductive film and the pattern on the top surface of the conductive film are both elliptical, which is beneficial to reducing the parasitic capacitance between the adjacent conductive films.

In some embodiments, by controlling the angle between an extension direction of at least one center line of the bottom surface of the capacitor contact window and an extension direction of the active region to be less than or equal to a predetermined value, misalignment between the capacitor contact window and the active region is reduced; in this case, when the bottom surfaces of the capacitor contact windows are the same in area, an contact area between the bottom surface of the capacitor contact window and the active region is relatively large, thus ensuring a good signal transmission performance of the capacitor contact window.

Correspondingly, an embodiment of the present disclosure further provides a memory, which can be manufactured by using the above-mentioned manufacturing method of a memory.

Referring to FIGS. 21 and 22, the memory includes: a substrate 10, active region 101 in the substrate 10, and bitline structures 11 on the substrate 10, the active region 101 extending in a first direction s1; and capacitor contact windows, the capacitor contact window being located between adjacent ones of the bitline structures 11, at least one center line of a bottom surface of the capacitor contact window extending in a second direction s2, an angle between the second direction s2 and the first direction s1 being less than or equal to 45 degrees.

In some embodiments, a bottom surface of the capacitor contact window is parallelogram-shaped, short sides of the parallelogram are close to the bitline structure 11, long sides of the parallelogram extend along the second direction s2. In other embodiments, the bottom surface of the capacitor contact window is parallelogram-shaped, long sides of the parallelogram are close to the bitline structure 11, and short sides of the parallelogram extend along the second direction s2.

In some embodiments, the capacitor contact window has an ellipse-shaped top surface and a parallelogram-shaped bottom surface, and a major axis of the ellipse extends in the second direction s2. In other embodiments, the top and bottom surfaces of the capacitor contact window are both ellipse-shaped, and a major axis of the ellipse extends in the second direction.

In some embodiments, the capacitor contact window includes a first cylinder in contact with the active region 101 and a second cylinder located on the first cylinder. The second cylinder has an ellipse-shaped top surface. In a plane parallel to the surface of the substrate 10, a cross-sectional area of the second cylinder is less than a cross-sectional area of the first cylinder.

In some embodiments, the first cylinder and the second cylinder are distinguished by the size of the cross-sectional area; in other embodiments, the first cylinder and the second cylinder are distinguished by the type of material.

In some embodiments, the memory further includes an isolation layer. The isolation layer is located between the bitline structures 11 and is configured to isolate adjacent capacitor contact windows. The isolation layer covers a top surface of the first cylinder exposed by the second cylinder. Specifically, the isolation layer includes a first isolation layer 14 and a second isolation layer 16 located on the first isolation layer 14. The second isolation layer 16 covers the top surface of the first cylinder exposed by the second cylinder.

In some embodiments, the capacitor contact windows are arranged in a quadrangular shape.

In some embodiments, by controlling the angle between an extension direction of at least one center line of the bottom surface of the capacitor contact window and an extension direction of the active region to be less than or equal to a predetermined value, misalignment between the capacitor contact window and the active region is reduced; in this case, when the bottom surfaces of the capacitor contact windows are the same in area, an contact area between the bottom surface of the capacitor contact window and the active region is relatively large, thus ensuring a good signal transmission performance of the capacitor contact window.

The ordinary skills in the art can understand that the implementations described above are particular embodiments for implementing the present disclosure. In practical uses, various changes in forms and details may be made to the implementations without departing from the spirit and scope of the present disclosure. Any person skilled in the art may make their own changes and modifications without departing from the spirit and scope of the present disclosure. Therefore, the protection scope of the present disclosure shall be subject to the protection scope of the claims.

What is claimed is:

1. A memory, comprising:
a substrate, active region in the substrate, and bitline structures on the substrate, the active region extending in a first direction; and
capacitor contact windows, the capacitor contact window being located between adjacent ones of the bitline structures, at least one center line of a bottom surface of the capacitor contact window extending in a second direction, an angle between the second direction and the first direction being less than or equal to 45 degrees.

2. The memory according to claim 1, wherein the bottom surface of the capacitor contact window is parallelogram-shaped, short sides of the parallelogram are close to the bitline structure, and long sides of the parallelogram extend along the second direction.

3. The memory according to claim 1, wherein the bottom surface of the capacitor contact window is parallelogram-shaped, long sides of the parallelogram are close to the bitline structure, and short sides of the parallelogram extend along the second direction.

4. The memory according to claim 1, wherein the bottom surface of the capacitor contact window is ellipse-shaped, and a major axis of the ellipse extends along the second direction.

5. The memory according to claim 1, wherein a top surface of the capacitor contact window is ellipse-shaped, and a major axis of the ellipse extends along the second direction.

6. The memory according to claim 5, wherein the capacitor contact window comprises a first cylinder in contact with the active region and a second cylinder located on the first cylinder, the second cylinder has an ellipse-shaped top surface, and in a plane parallel to a surface of the substrate, a cross-sectional area of the second cylinder is less than a cross-sectional area of the first cylinder.

7. The memory according to claim 6, further comprising: an isolation layer, the isolation layer being located between adjacent ones of the bitline structures and configured to isolate adjacent ones of the capacitor contact windows, the isolation layer covering a top surface of the first cylinder exposed by the second cylinder.

8. The memory according to claim 5, wherein the capacitor contact windows are arranged in a quadrangular shape.

9. A manufacturing method of a memory, comprising:
providing a substrate, active region in the substrate, and bitline structures on the substrate, the active region extending along a first direction;
forming a sacrificial layer filled between adjacent ones of the bitline structures, and forming a mask layer covering a top surface of the sacrificial layer, the mask layer being configured to form an isolation layer; and
forming the isolation layer and capacitor contact windows between adjacent ones of the isolation layers, at least one center line of a bottom surface of the capacitor contact window extending in a second direction, an angle between the second direction and the first direction being less than or equal to 45 degrees.

10. The manufacturing method of a memory according to claim 9, wherein the process step of forming the capacitor contact window comprises: forming first isolation layers, as well as a conductive film and a shielding layer located between adjacent ones of the first isolation layers, the shielding layer being located on the conductive film; carrying out a wet etching process to remove part of the first isolation layer to smoothen sidewalls of the shielding layer; and etching at least part of the conductive film by using the smoothened shielding layer as a mask, a remaining part of the conductive film functioning as the capacitor contact window.

11. The manufacturing method of a memory according to claim 10, wherein in the same etching process, at least part of the conductive film and at least part of the first isolation layer are etched; after the first isolation layer is etched, the method further comprises: forming a second isolation layer filled between adjacent ones of the conductive films, a top surface of the second isolation layer being flush with a top surface of the capacitor contact window, the second isolation layer and the first isolation layer constituting the isolation layer.

12. The manufacturing method of a memory according to claim 10, wherein the etching at least part of the conductive film comprises: etching through the conductive film so that a pattern on a bottom surface of the conductive film is the same as a pattern on a top surface of the conductive film.

13. The manufacturing method of a memory according to claim 10, wherein a top surface of the shielding layer before smoothening is parallelogram-shaped, and the top surface of the smoothened shielding layer is ellipse-shaped.
